(19) United States
(12) Patent Application Publication
(10) Pub. No.: US 2008/0079038 A1
(43) Pub. Date: Apr. 3, 2008

(54) Semiconductor devices with gate insulation layers having different thicknesses and methods of forming the same

(76) Inventors: Tae-Kyung Kim, Seoul (KR); Woon-Kyung Lee, Gyeonggi-do (KR)

Correspondence Address: MYERS BIGEL SIBLEY & SAJOVEC, PO BOX 37428, RALEIGH, NC, 27627, US

(21) Appl. No.: 11/646,127

(22) Filed: Dec. 27, 2006

(30) Foreign Application Priority Data
Oct. 2, 2006 (KR) 10-2006-097294

(51) Int. Cl. H01L 29/76

(52) U.S. Cl. 257/288

(57) ABSTRACT

Methods of forming a semiconductor device include an active region and a shallow trench isolation region in a semiconductor substrate, and forming a gate insulation layer on the active region. The gate insulation layer includes a first part spaced apart from the shallow trench isolation region and a second part adjacent the shallow trench isolation region and disposed between the shallow trench isolation region and the first part, and thicker than the first part. The methods further include forming a first impurity region in the active region of the semiconductor substrate adjacent the first part, and forming a gate line on the gate insulation layer. Corresponding semiconductor devices are also disclosed.

### CROSS-REFERENCE TO RELATED APPLICATION

This patent application claims priority under 35 U.S.C. §119 to Korean Patent Application No. 10-2006-097294, filed on Oct. 2, 2006, the disclosure of which is hereby incorporated by reference.

### FIELD OF THE INVENTION

The present invention relates to semiconductor devices and methods of forming the same, and more particularly, to semiconductor memory devices having gate insulation layers and methods of forming the same.

### BACKGROUND

Semiconductor memory devices may be categorized as volatile memory devices that do not hold their contents without power or non-volatile memory devices that may hold their contents for a period of time without power. A flash memory device is a non-volatile memory device that may be highly integrated and that may have advantages similar to an erasable programmable read only memory (EPROM) and/or an electrically erasable programmable read only memory (EEPROM).

A flash memory device includes a high voltage transistor in a peripheral region. The high voltage transistor has a high breakdown voltage, which can be obtained by thickening a gate insulation layer in a high-voltage transistor. However, increasing the thickness of the gate insulation layer may increase a body effect that may change the threshold voltage of the device.

FIG. 1 is a plan view of a conventional semiconductor device, and FIG. 2 is a sectional view taken along line I-I′ of FIG. 1.

Referring to FIGS. 1 and 2, an active region 10 is defined by a device isolation region 20 of a semiconductor substrate 10. A gate insulation layer 30 is provided on the active region 10. The gate insulation layer 30, for example, may have a thickness of 350 A. A gate line 40 is provided to cross over the gate insulation layer 30 and the device isolation region 20. During formation of the device isolating region 20, etch damage may occur in edges (shown in dotted lines) of the gate insulation layer 30 contacting the device isolation region 20. Since the area adjacent to the active region 10 and the device isolation region 20 may have a relatively large influence on the gate electric field and is adjacent to an ion implantation region, breakdown may occur at the edges of the gate insulation layer 30. Accordingly, the breakdown characteristics of the semiconductor device may deteriorate.

### SUMMARY

A semiconductor device according to some embodiments of the invention includes a semiconductor substrate including an active region and a shallow trench isolation region adjacent the active region, and a gate insulation layer in the active region. The gate insulation layer includes a first part and a second part. The first part of the gate insulation layer is spaced apart from the shallow trench isolation region. The second part of the gate insulation layer is adjacent the shallow trench isolation region and is disposed between the shallow trench isolation region and the first part of the gate insulation layer, and is thicker than the first part of the gate insulation layer. The device further includes a first impurity region in the active region adjacent the first part of the gate insulation layer, and a gate line on the gate insulation layer. The first impurity region may be aligned below the first part of the gate insulation layer.

The semiconductor device may further include a second impurity region disposed adjacent the second part and extending shallower into the substrate than the first impurity region. The second impurity region may have an impurity concentration lower than an impurity concentration of the first impurity region.

The device may further include a second active region and a second gate insulation layer on the second active region, and the first part of the gate insulation layer may have a thickness different from a first part of the second gate insulation layer. Furthermore, the second part of the gate insulation layer may have a width different from a second part of the second gate insulation layer.

Methods of forming a semiconductor device according to some embodiments of the invention include forming an active region and a shallow trench isolation region in a semiconductor substrate, and forming a gate insulation layer on the active region. The gate insulation layer includes a first part spaced apart from the shallow trench isolation region and a second part adjacent the shallow trench isolation region and disposed between the shallow trench isolation region and the first part, and thicker than the first part. The methods further include forming a first impurity region in the active region of the semiconductor substrate adjacent the first part, and forming a gate line on the gate insulation layer.

Forming the gate insulation layer may include forming a preliminary gate insulation layer on the active region, forming a photoresist pattern exposing a central portion of the preliminary gate insulation layer, and etching the central portion of the preliminary gate insulation layer using the photoresist pattern as an etching mask, such that the first part of the gate insulation layer corresponds to the recessed central portion. Etching the preliminary gate insulation layer may include performing a wet etch process.

Forming the first impurity region may include implanting ions into the semiconductor substrate using the photoresist pattern as an ion implantation mask.

The methods may further include removing at least the portion of the photoresist pattern covering the gate insulation layer after forming the gate insulation layer, and forming a second impurity region below the second part by implanting ions into the semiconductor substrate through the gate insulation layer.

Methods of forming a semiconductor device according to further embodiments of the invention include forming a shallow trench isolation region in a semiconductor substrate to thereby define a first active region and a second active region in the semiconductor substrate, and forming a first gate insulation layer including a first part and a second part on the first active region and a second gate insulation layer including a first part and a second part on the second active region. The first part of a respective gate insulation layer is spaced apart from the shallow trench isolation region, and the second part of a respective gate insulation layer is below the shallow trench isolation region and is disposed between the shallow trench isolation region and the respective first part, and is thicker than the respective first part.

The methods further include forming first impurity regions below the respective first parts of the first gate insulation layer and the second gate insulation layer, and forming a gate line crossing over the first active region, the second active region, and the shallow trench isolation region.

Forming the first gate insulation layer and the second gate insulation layer may include forming a first preliminary gate insulation layer and a second preliminary gate insulation layer on the first active region and the second active region, respectively, forming a first photoresist pattern exposing a central portion of the first preliminary gate insulation layer, and etching the central portion of the first preliminary gate insulation layer using the first photoresist pattern as an etching mask. The first photoresist pattern is removed, and a second photoresist pattern is formed to expose a central portion of the second preliminary gate insulation layer. The central portion of the second gate insulation layer is etched using the second photoresist pattern as an etching mask.

The etched central portion of the first gate insulation layer (corresponding to the first part of the first gate insulation layer) has a thickness different from the etched central portion of the second gate insulation layer (corresponding to the first part of the second gate insulation layer).

Etching the first preliminary gate insulation layer and the second preliminary gate insulation layer include performing wet etch processes.

Forming the first impurity region may include implanting ions using the first photoresist pattern as an ion implantation mask, and forming the second impurity region may include implanting ions using the second photoresist pattern as an ion implantation mask.

Forming the first impurity region may include removing the second photoresist pattern after etching the second preliminary gate insulation layer, and forming a second impurity region below the second part of the first gate insulation layer by implanting ions into the semiconductor substrate.

Forming the first gate insulation layer and the second gate insulation layer may include forming a first preliminary gate insulation layer and a second preliminary gate insulation layer on the first active region and the second active region, respectively, and forming a photoresist pattern exposing a central portion of the first preliminary gate insulation layer and a central portion of the second preliminary gate insulation layer. The central portion of the first preliminary gate insulation layer may have a width different from the width of the central portion of the second preliminary gate insulation layer. The methods may further include etching a recess in the first preliminary gate insulation layer and a recess the second preliminary gate insulation layer using the photoresist pattern as an etching mask, such that the recess in the first gate insulation layer has a width different from the recess in the second gate insulation layer.

Forming the first impurity region may include implanting ions into the semiconductor substrate using the photoresist pattern as an ion implantation mask.

Forming the first impurity region may include removing the photoresist pattern after etching the first preliminary gate insulation layer and the second preliminary gate insulation layer, and implanting ions into the semiconductor substrate through the first gate insulation layer and the second gate insulation layer.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1 is a plan view of a conventional semiconductor device;

FIG. 2 is a sectional view taken along line I-I′ of FIG. 1;

FIG. 3 is a plan view of a semiconductor device according to some embodiments of the present invention;

FIG. 4 is a sectional view taken along line II-II′ of FIG. 3;

FIG. 5 is a perspective view of a semiconductor device according to some embodiments of the present invention;

FIGS. 6A through 6D are sectional views illustrating methods for forming a semiconductor device according to some embodiments of the present invention;

FIG. 7 is a sectional view of a semiconductor device according to some embodiments of the present invention;

FIGS. 8A through 8F are sectional views illustrating methods for forming a semiconductor device according to some embodiments of the present invention; and

FIGS. 9A through 9D are sectional views illustrating methods for forming a semiconductor device according to some embodiments of the present invention.

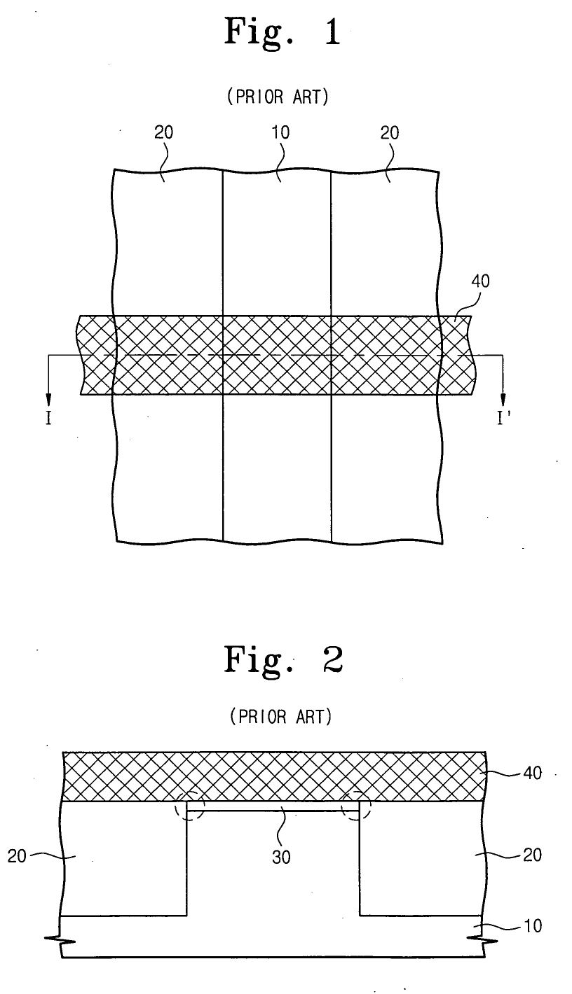

### DETAILED DESCRIPTION OF EMBODIMENTS OF THE INVENTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

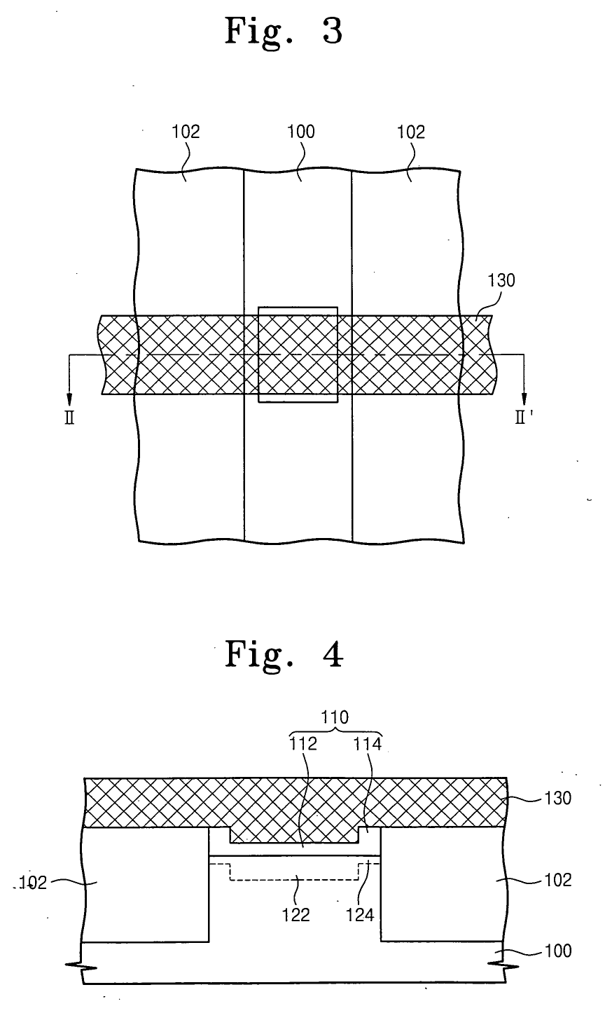

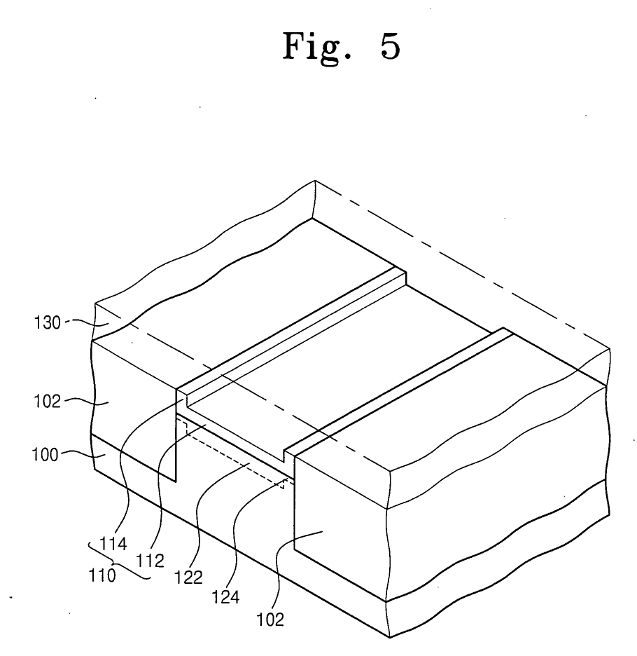

FIG. 3 is a plan view of a semiconductor device according to some embodiments of the present invention. FIG. 4 is a sectional view taken along line II-II′ of FIG. 3. FIG. 5 is a perspective view of a semiconductor device according to some embodiments of the present invention.

Referring to FIGS. 3 through 5, an active region is defined on a semiconductor substrate 100 by a device isolation region 102. A gate insulation layer 110 is provided on the active region. The gate insulation layer 110 may include a silicon oxide layer. The gate insulation layer 110 includes a first part 112 spaced apart from the device isolation region 102 and a second part 114 contacting the device isolation region 102 and thicker than the first part 112. The second part 114 is provided between the device isolation region 102 and the first part 112. Since the second part 114 is thicker than the first part, a breakdown voltage may be increased near edges of the gate insulation layer 110 that contact the device isolation region 102.

A first impurity region 122 is provided below the first part 112 of the gate insulation layer 110. The first impurity region 122 may affect a threshold voltage of the device. The first impurity region 122 may be self-aligned below the first part 112. Since the first impurity region 122 is provided below the first part 112 and is spaced apart from the device isolation region 102, a breakdown phenomenon can be reduced and/or prevented near edges of the gate insulation layer 110 that contact the device isolation region 102.

A second impurity region 124 is provided below the second part 114 of the gate insulation layer 110. The second impurity region 124 may be shallower than the first impurity region 122. That is, the second impurity region 124 may extend a shorter distance into the substrate 100 than the first impurity region 122. The impurity concentration of the second impurity region 124 may be lower than that of the first impurity region 122. Although the second impurity region 124 is provided, breakdown can be reduced near edges of the gate insulation layer 110 that contact the device isolation region 102, because the impurity concentration of the second impurity region 124 may be lower than that of the first impurity region 122. A gate line 130 is provided to cross over the active region and the device isolation region 102. The gate line 130 may include, for example, a gate electrode and a hard mask layer.

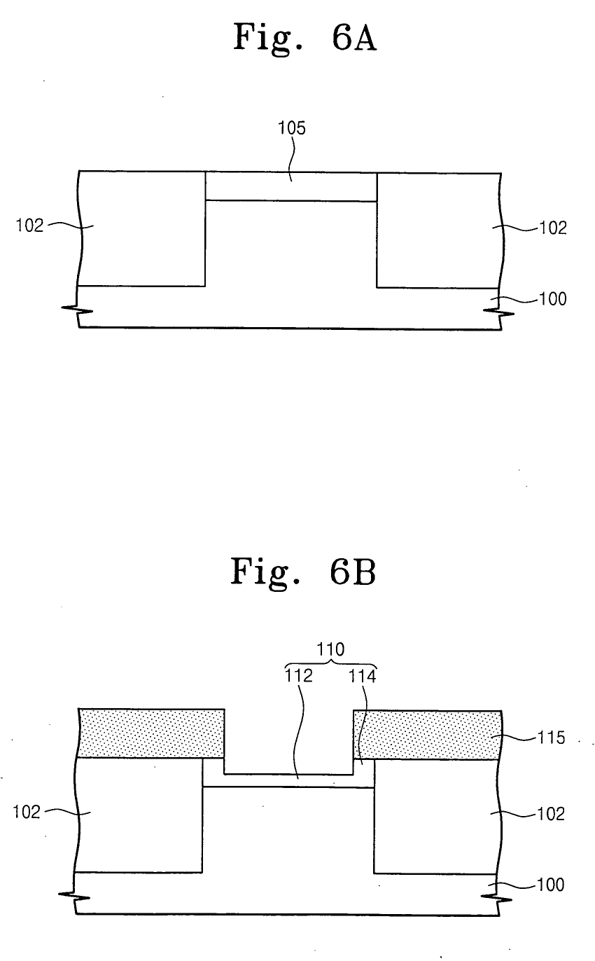

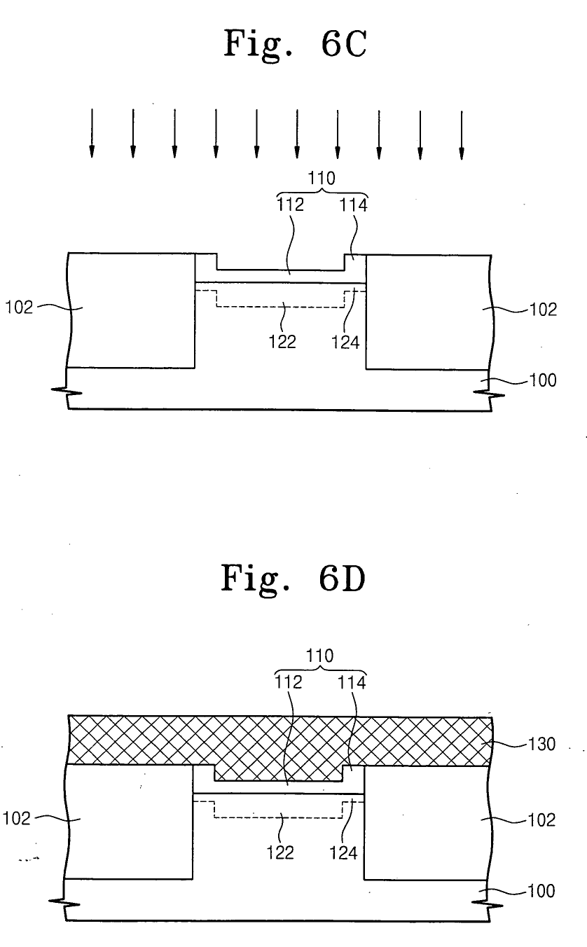

FIGS. 6A through 6D are sectional views illustrating some methods of forming semiconductor devices according to some embodiments of the present invention.

Referring to FIG. 6A, a device isolation region 102 is formed on a semiconductor substrate 100. The device isolation region 102 may be formed, for example, using a shallow trench isolation (STI) process in which a planarization process is performed after forming a trench on the semiconductor substrate 100 and depositing an insulation layer in the trench. When the device isolation region 102 is formed, etch damage may occur at or near edges of an active region contacting the device isolation region 102. The etching damage may cause breakdown in a subsequently formed gate insulation layer. In order to reduce and/or avoid potential breakdowns, a preliminary gate insulation layer 105 may be formed on an active region defined by the device isolation region 102. The preliminary insulation layer 105 may include a silicon oxide layer that may be formed by, for example, using a thermal oxide process.

Referring to FIG. 6B, a photoresist pattern 115 is formed to expose a central portion of the preliminary gate insulation layer 105 that is spaced apart from the device isolation region 102. A gate insulation layer 110 is formed by performing an etching process that uses the photoresist pattern 115 as an etching mask. The etching process may be a wet etching process that may use a solution including HF. The resulting gate insulation layer 110 includes a first part 112 spaced apart from the device isolation region 102 and a second part 114 contacting the device isolation region 102 and thicker than the first part 112. The second part 114 is formed between the device isolation region 102 and the first part 112. For example, the first part 112 may have a thickness of about 350 Å, and the second part 114 may have a thickness of about 380 Å. A breakdown phenomenon caused by etching damage during the forming of the device isolation region 102 can be reduced and/or prevented by thickening the second part 114.

Referring to FIG. 6C, a first impurity region 122 and a second impurity region 124 are formed by performing an ion implantation process on the semiconductor substrate 100. The first impurity region 122 may be self-aligned below the first part 112. The second impurity region 124 is formed below the second part 114. The second impurity region 124 may be shallower than the first impurity region 122 due to the presence of the second part 114. Furthermore, the impurity concentration of the second impurity region 124 may be lower than that of the first impurity region 122.

On the other hand, if the photoresist pattern 115 is used as an ion implantation mask, the second impurity region 124 may not be formed. If the second impurity region 124 is not formed below the second part 114, the breakdown characteristics of the gate insulation layer 110 can be improved more. As the photoresist pattern 115 may be used as an ion implantation mask and an etching mask, the gate insulation layer 110 and the first impurity region 122 may be formed without an additional photolithography step.

Referring to FIG. 6D, a gate line 130 may be formed to cross over the active region and the device isolation region 102. Forming the gate line 130 may include forming a hard mask layer after forming a gate electrode. An operation current of a transistor can be maintained by forming the first part 112 of the gate insulation layer 110 to be thin. Since the second part 114 is formed thicker than the first part 112, and the impurity concentration of the second impurity region 124 is lower than that of the first part 112, the breakdown characteristics of the device can be improved.

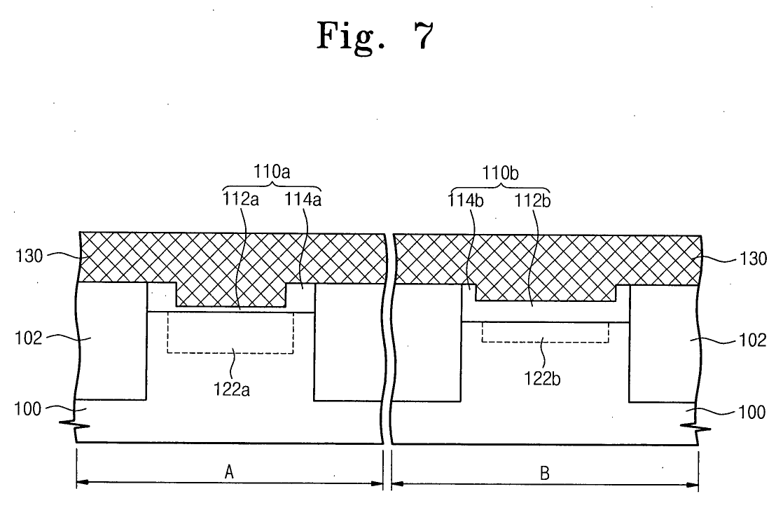

FIG. 7 is a sectional view of a semiconductor device according to some embodiments of the present invention.

Referring to FIG. 7, a semiconductor substrate 100 includes a first region A and a second region B. A first active region of the first region A and a second active region of the second region B are defined by a device isolation region 102 provided on the semiconductor substrate 100. A first gate insulation layer 110a is provided on the first active region. The gate insulation layer 110a includes a first part 112a spaced apart from the device isolation region 102 and a second part 114a contacting the device isolation region 102 and thicker than the first part 112a. A second gate insulation layer 110b is provided on the second active region. The second gate insulation layer 110b includes a first part 112b spaced apart from the device isolation region 102 and a second part 114b contacting the device isolation region 102 and thicker than the first part 112b. The first gate insulation layer 110a and the second gate insulation layer 110b may include a silicon oxide layer.

The thickness of the first part 112a of the first gate insulation layer 110a may be thinner than that of the first part 112b of the second gate insulation layer 110b, or vice-versa. The width of the second part 114a of the first gate insulation layer 110a may be wider than the second part 114b of the second gate insulation layer 110b, or vice-versa. Various transistors having different breakdown characteristics and/or threshold voltages can be provided by adjusting the thicknesses of the first parts 112a and 112b and/or the widths of the second parts 114a and 114b.

First impurity regions 122a and 122b are respectively provided below the first parts 112a and 112b. The first impurity region 122a of the first active region may extend deeper than the first impurity region 122b of the second active region. The reason is that a thickness of the first part 112a of the first gate insulation layer 110a may be thinner than the first part 112b of the second gate insulation layer 110b. Since the first impurity regions 122a and 122b are provided below the first parts 112a and 112b, a breakdown phenomenon can be reduced and/or prevented in the second parts 114a and 114b. A gate line 130 is provided to cross over the device isolation region 102, the first active region, and the second active region. The gate line 130 may include a gate electrode and a hard mask layer.

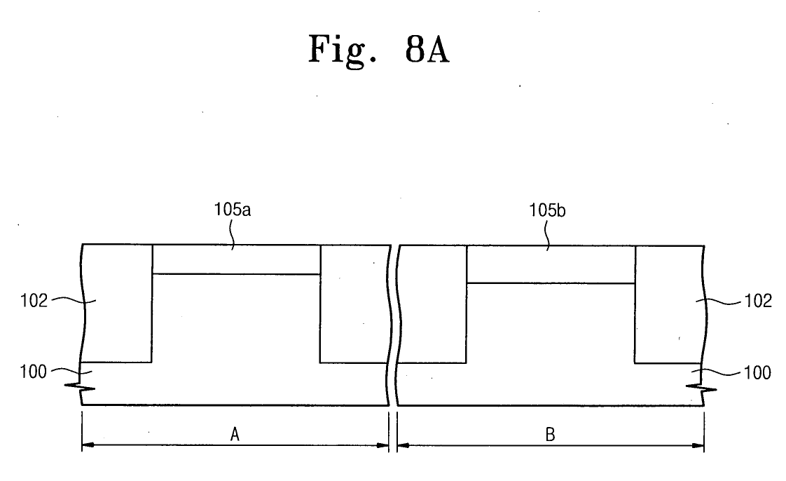

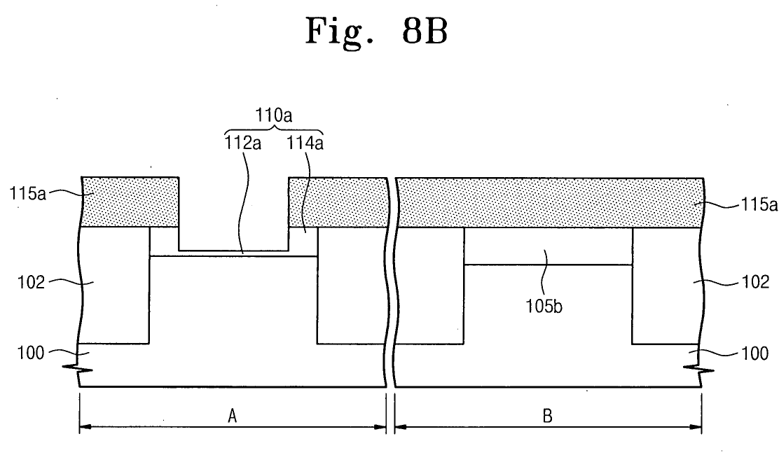

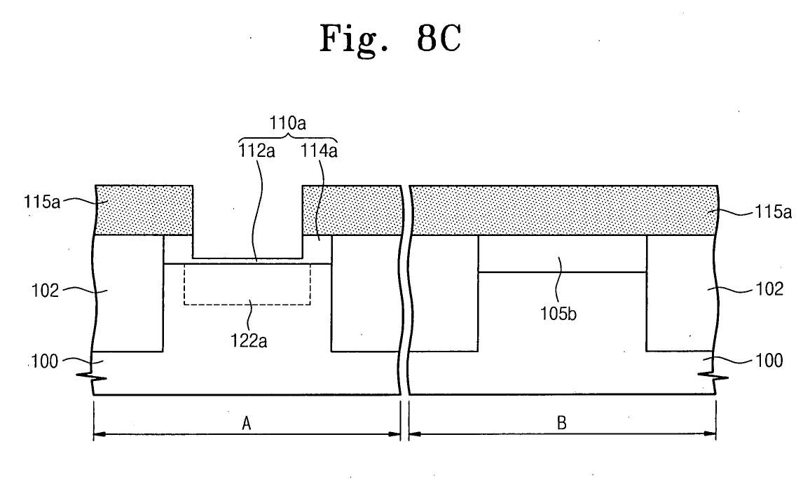

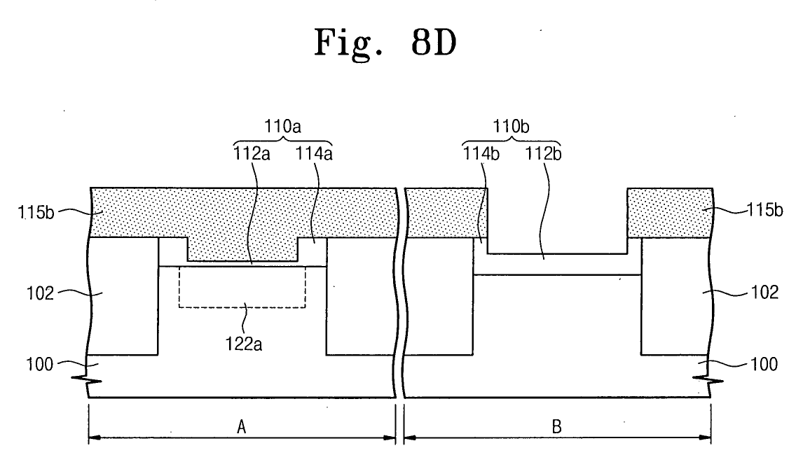

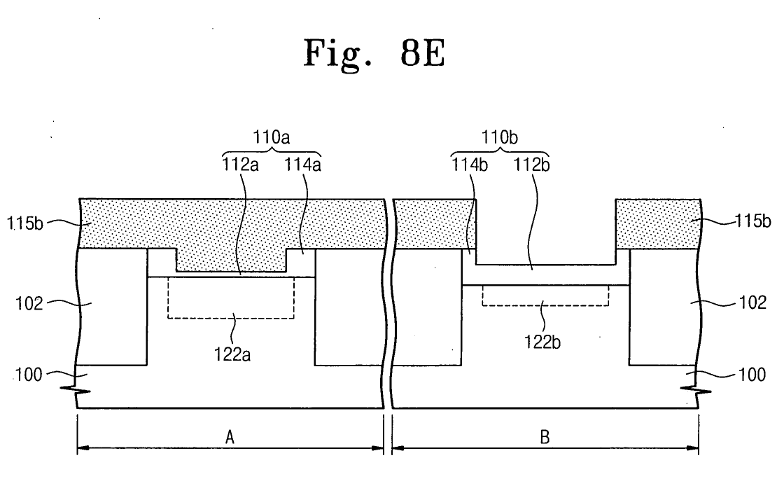

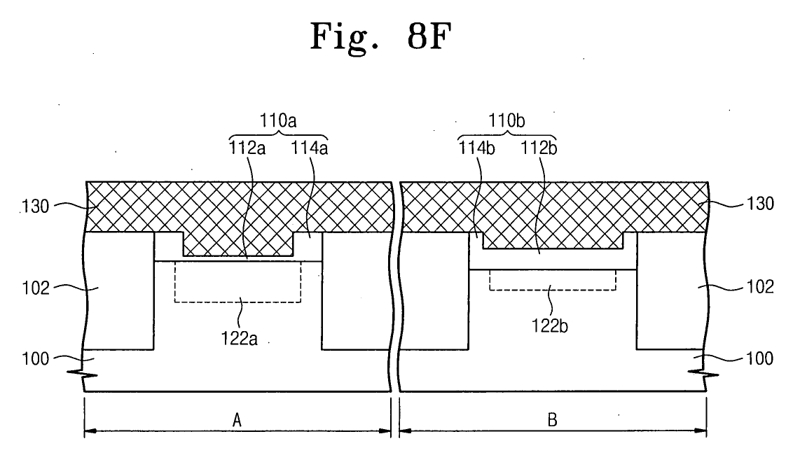

FIGS. 8A through 8F are sectional views illustrating methods for forming semiconductor devices according to some embodiments of the present invention.

Referring to FIG. 8A, a device isolation region 102 may be formed on a semiconductor substrate 100 including a first region A and a second region B, for example using an STI process. A first active region and a second active region are defined in the first region A and the second region B, respectively by the device isolation region 102. A first preliminary gate insulation layer 105a and a second preliminary gate insulation layer 105b are formed on the first active region and the second active region, respectively. The first preliminary gate insulation layer 105a and the second preliminary gate insulation layer 105b may include a silicon oxide layer formed, for example, using a thermal oxide process.

Referring to FIG. 8B, a first photoresist pattern 115a is formed to expose a central portion of the preliminary gate insulation layer 105a. A first wet etching process may be performed using the first photoresist pattern 115a as an etching mask, thereby forming a first gate insulation layer 110a. The first wet etching process may use a solution including, for example, HF. The gate insulation layer 110a includes a first part 112a spaced apart from the device isolation region 102 and a second part 114a disposed between the device isolation region 102 and the first part 112a and thicker than the first part 112a. Since the second part 114a is formed thicker than the first part 112a, a breakdown phenomenon can be reduced and/or prevented.

Referring to FIG. 8C, an ion implantation process is performed using the first photoresist pattern 115a as an ion implantation mask, thereby forming a first impurity region 122a that is self-aligned below the first part 112a. Since the photoresist pattern 115a is used as an ion implantation mask and an etching mask, the gate insulation layer 110a and the first impurity region 122a may be formed without an additional photolithography step. Therefore, a breakdown phenomenon can be reduced and/or prevented in the second part 114a.

Referring to FIG. 8D, a second photoresist pattern 115b is formed to expose a central portion of the second preliminary insulation layer 105b on the second active region. A second wet etching process may be performed using the second photoresist pattern 115b as an etching mask, thereby forming a second gate insulation layer 110b. The second wet etching process may use a solution including, for example, HF. The second gate insulation layer 110b includes a first part 112b spaced apart from the device isolation region 102 and a second part 114b disposed between the device isolation region 102 and the first part 112b and thicker than the first part 112b. As the first wet etching process and the second wet etching process are performed, for example, a thickness of the first part 112b of the second gate insulation layer 110b may be different from that of the first part 112a of the first gate insulation layer 110a. The widths of the second parts 114a and 114b may be changed by adjusting openings of the first photoresist pattern 115a and the second photoresist pattern 115b.

Referring to FIG. 8E, an ion implantation process is performed using the second photoresist pattern 115b as an ion implantation mask, thereby forming a first impurity region 122b that is self-aligned below the first part 112b. The first impurity region 122b of the second active region may be formed to be shallower than the first impurity region 122a of the first active region. The reason is that the thickness of the first part 112b in the second active region is thicker than that of the first part 112a of the first active region, assuming similar implant conditions are used.

In some embodiments, forming the first impurity regions 122a and 122b in the first active region and the second active region may include removing the second photoresist pattern 115b after performing the second wet etching process, and forming a second impurity region below the second parts 114a and 114b by performing an ion implantation process on the first active region and the second active region. In forming the second impurity region, the first photoresist pattern 115a and the second photoresist pattern 115b may not be used as ion implantation masks. In that case, the second impurity region may be formed according to the width and thickness of the second parts 114a and 114b. The second impurity region may be formed to be shallower than the first impurity regions 122a and 122b, and may include an impurity concentration lower than that of the first impurity regions 122a and 122b.

Referring to FIG. 8F, a gate line 130 is formed to cross over the device isolation region 102, the first active region, and the second active region. Forming the gate line 130 may include forming a gate electrode and a hard mask layer. The first gate insulation layer 110a and the second gate insulation layer 110b may be patterned using by the first photoresist pattern 115a and the second photoresist pattern 115b, respectively. Therefore, the thickness of the first parts 112a and 112b and the width of the second parts 114a and 114b can be adjusted independently. The depth and the concentration of each of the first impurity regions 122a and 122b can be adjusted using the first gate insulation layer 110a and the second gate insulation layer 10b and/or by varying the implant conditions.

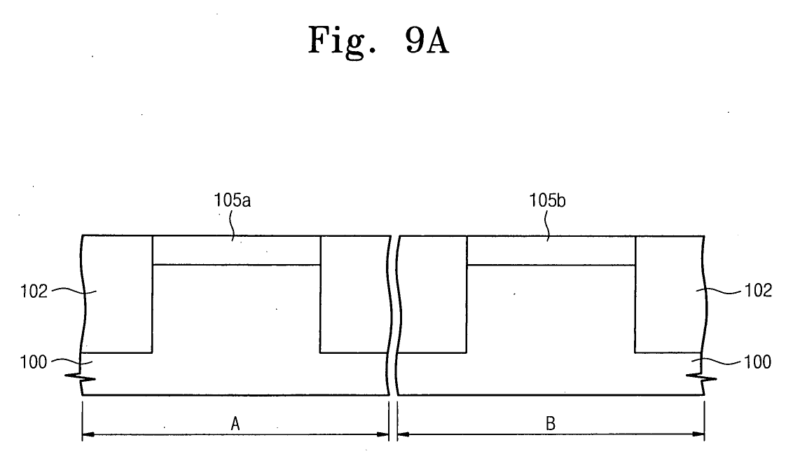

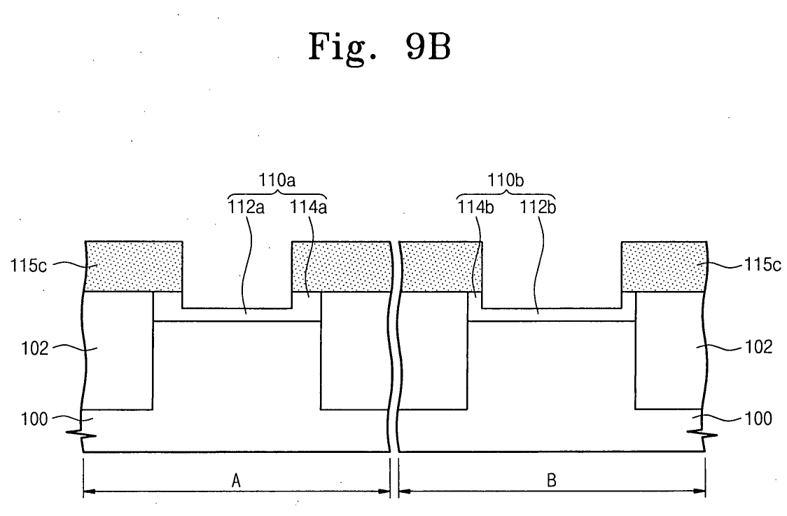

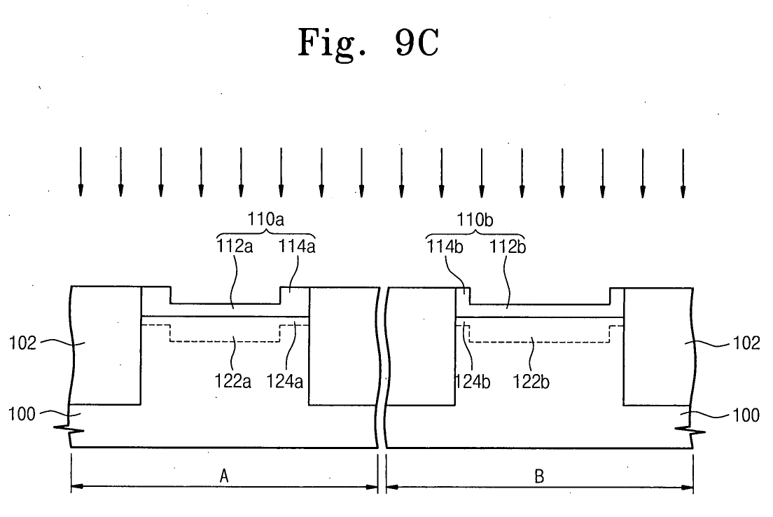

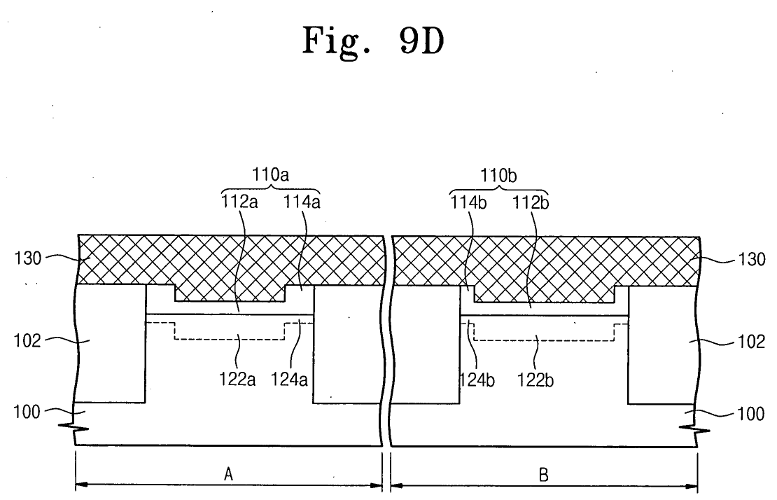

FIGS. 9A through 9D are sectional views illustrating methods for forming semiconductor devices according to some embodiments of the present invention.

Referring to FIG. 9A, an STI process may be performed on a semiconductor substrate 100 including a first region A and a second region B, thereby forming a device isolation region 102. A first active region and a second active region are respectively defined on the first region A and the second region B by the device isolation region 102. A first preliminary gate insulation layer 105a and a second preliminary gate insulation layer 105b are formed on the first active region and the second active region, respectively. The first preliminary gate insulation layer 105a and the second preliminary gate insulation layer 105b may include a silicon oxide layer formed by a thermal oxide process.

Referring to FIG. 9B, a photoresist pattern 115c may be formed to expose a central area of the first preliminary gate insulation layer 105a and the second preliminary gate insulation layer 105b. A wet etching process may be performed using the photoresist pattern 115c as an etching mask, thereby forming a first gate insulation layer 110a and a second gate insulation layer 110b. The first gate insulation layer 110a and the second gate insulation layer 110b may include the first parts 112a and 112b spaced apart from the device isolation region 102 and the second parts 114a and 114b, wherein the second part 114a is disposed between the device isolation region 102 and the first part 112a and is thicker than the first part 112a, and the second part 114b is disposed between the device isolation region 102 and the first part 112b and is thicker than the first part 112b. Since the first part 112a of the first gate insulation layer 110a and the first part 112b of the second gate insulation layer 110b may be formed using the same wet etching process, a similar thickness can be achieved.

Referring to FIG. 9C, after at least partially removing the photoresist pattern 115c, an ion implantation process may be performed to form first impurity regions 122a and 122b that are self-aligned below the first parts I 12a and 112b. Forming the first impurity regions 122a and 122b may include forming the second impurity regions 124a and 124b below the second parts 114a and 114b, respectively. The second impurity regions 124a and 124b may be shallower than the first impurity regions 122a and 122b, respectively. An impurity concentration of the second impurity regions 124a and 124b may be lower than that of the first impurity regions 122a and 122b. In some cases, after performing a wet etching process, an ion implantation process may be performed by using the photoresist pattern 115c as an ion implantation mask to form the first impurity regions 122a and 122b.

Referring to FIG. 9D, a gate line 130 is formed to cross over the device isolation region 102, the first active region, and the second active region. Forming the gate line 130 may include forming a gate electrode and a hard mask layer. Since the first gate insulation layer 110a and the second gate insulation layer 110b may be formed using the same photoresist pattern, the first part 112a, 112b can be formed to have similar thicknesses, and the second parts 114a and 114b can be formed to have different widths. Moreover, the first impurity regions 122a and 122b and the second impurity regions 124a and 124b can be formed on the first gate insulation layer 110a and the second gate insulation layer 110b, respectively, according to the widths and the thicknesses of the first parts 112a, 112b and the second parts 114a, 114b.

According to some embodiments of the present invention, a gate insulation layer may be formed to include a first part spaced apart from a device isolation region, and a second part contacting the device isolation region and thicker than the first part. Accordingly, a breakdown phenomenon can be reduced and/or prevented in a region contacting the device isolation region.

Moreover, since an impurity region may be formed below a portion spaced apart from a device isolation region, a breakdown phenomenon can be reduced and/or prevented.

In some embodiments an ion implantation mask may be used as an etching mask to form a gate insulation layer having different thicknesses which may reduce the number of photolithography steps needed to form the device.

According to some embodiments of the present invention, as a wet etching process may be performed using each photoresist pattern, gate insulation layers can be formed to have various widths and/or thicknesses. According to the width and/or thickness of the gate insulation layer, an impurity region can be formed to improve the breakdown characteristics of a device.

According to some embodiments of the present invention, since a wet etching process may be performed using the same photoresist pattern, gate insulation layers can be formed to have various widths in a portion contacting a device isolation layer, and a similar thicknesses in an area spaced apart from the device isolation region. Accordingly, breakdown characteristics of a semiconductor device can be improved.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A semiconductor device, comprising:
a semiconductor substrate including an active region and a shallow trench isolation region adjacent the active region;
a gate insulation layer in the active region, the gate insulation layer including a first part and a second part, the first part spaced apart from the shallow trench isolation region and the second part adjacent the shallow trench isolation region, wherein the second part is disposed between the shallow trench isolation region and the first part, and is thicker than the first part;
a first impurity region in the active region adjacent the first part; and
a gate line on the gate insulation layer.

2. The semiconductor device of claim 1, wherein the first impurity region is aligned below the first part.

3. The semiconductor device of claim 1, further comprising a second impurity region disposed adjacent the second part and extending shallower into the substrate than the first impurity region.

4. The semiconductor device of claim 3, wherein the second impurity region has an impurity concentration lower than an impurity concentration of the first impurity region.

5. The semiconductor device of claim 1, wherein the active region comprises a first active region and the gate insulation layer comprises a first gate insulation layer, the device further including a second active region and a second gate insulation layer on the second active region, wherein the first part of the first gate insulation layer has a thickness different from a first part of the second gate insulation layer.

6. The semiconductor device of claim 1, wherein the active region comprises a first active region and the gate insulation layer comprises a first gate insulation layer, the device further including a second active region and a second gate insulation layer on the second active region, wherein the second part of the first gate insulation layer has a width different from a second part of the second gate insulation layer.

7. The semiconductor device of claim 1, wherein the active region comprises a first active region and the gate insulation layer comprises a first gate insulation layer, the device further including a second active region and a second gate insulation layer on the second active region, wherein the first part of the first gate insulation layer has a thickness different from a first part of the second gate insulation layer, and wherein the second part of the first gate insulation layer has a width different from a second part of the second gate insulation layer.

8. A method of forming a semiconductor device, comprising:
forming an active region and a shallow trench isolation region in a semiconductor substrate;
forming a gate insulation layer on the active region, the gate insulation layer including a first part spaced apart from the shallow trench isolation region and a second part adjacent the shallow trench isolation region, wherein the second part is disposed between the shallow trench isolation region and the first part and is thicker than the first part;
forming a first impurity region in the active region of the semiconductor substrate adjacent the first part; and
forming a gate line on the gate insulation layer.

9. The method of claim 8, wherein forming the gate insulation layer comprises:
forming a preliminary gate insulation layer on the active region;
forming a photoresist pattern exposing a central portion of the preliminary gate insulation layer; and
etching the central portion of the preliminary gate insulation layer using the photoresist pattern as an etching mask, wherein the first part of the gate insulation layer corresponds to the recessed central portion.

10. The method of claim 9, wherein etching the preliminary gate insulation layer comprises performing a wet etch process.

11. The method of claim 9, wherein forming the first impurity region comprises implanting ions into the semiconductor substrate using the photoresist pattern as an ion implantation mask.

12. The method of claim 9, further comprising:
removing at least the portion of the photoresist pattern covering the gate insulation layer after forming the gate insulation layer; and
forming a second impurity region below the second part by implanting ions into the semiconductor substrate through the gate insulation layer.

13. A method of forming a semiconductor device, comprising:
forming a shallow trench isolation region in a semiconductor substrate to thereby define a first active region and a second active region in the semiconductor substrate;
forming a first gate insulation layer including a first part and a second part on the first active region and a second gate insulation layer including a first part and a second part on the second active region, wherein the first part of a respective gate insulation layer is spaced apart from the shallow trench isolation region, and wherein the second part of a respective gate insulation layer is adjacent the shallow trench isolation region and is disposed between the shallow trench isolation region and the respective first part, and is thicker than the respective first part;
forming first impurity regions adjacent the respective first parts of the first gate insulation layer and the second gate insulation layer; and
forming a gate line crossing over the first active region, the second active region, and the shallow trench isolation region.

14. The method of claim 13, wherein forming the first gate insulation layer and the second gate insulation layer comprises:
forming a first preliminary gate insulation layer and a second preliminary gate insulation layer on the first active region and the second active region, respectively;
forming a first photoresist pattern exposing a central portion of the first preliminary gate insulation layer;
etching the central portion of the first preliminary gate insulation layer using the first photoresist pattern as an etching mask;
removing the first photoresist pattern;
forming a second photoresist pattern exposing a central portion of the second preliminary gate insulation layer; and
etching the central portion of the second preliminary gate insulation layer using the second photoresist pattern as an etching mask;
wherein the etched central portion of the first gate insulation layer corresponding to the first part of the first gate insulation layer has a thickness different from the etched central portion of the second gate insulation layer corresponding to the first part of the second gate insulation layer.

15. The method of claim 14, wherein etching the first preliminary gate insulation layer and the second preliminary gate insulation layer comprise performing wet etch processes.

16. The method of claim 14, wherein forming the first impurity region comprises:
implanting ions using the first photoresist pattern as an ion implantation mask; and
wherein forming the second impurity region comprises implanting ions using the second photoresist pattern as an ion implantation mask.

17. The method of claim 14, wherein forming the first impurity region comprises:
removing the second photoresist pattern after etching the second preliminary gate insulation layer; and
forming a second impurity region adjacent the second part of the first gate insulation layer by implanting ions into the semiconductor substrate.

18. The method of claim 13, wherein forming the first gate insulation layer and the second gate insulation layer comprises:
forming a first preliminary gate insulation layer and a second preliminary gate insulation layer on the first active region and the second active region, respectively;
forming a photoresist pattern exposing a central portion of the first preliminary gate insulation layer and a central portion of the second preliminary gate insulation layer, wherein the central portion of the first preliminary gate insulation layer has a width different from the width of the central portion of the second preliminary gate insulation layer; and
etching a recess in the first preliminary gate insulation layer and a recess the second preliminary gate insulation layer using the photoresist pattern as an etching mask, wherein the recess in the first gate insulation layer has a width different from the recess in the second gate insulation layer.

19. The method of claim 18, wherein forming the first impurity region comprises implanting ions into the semiconductor substrate using the photoresist pattern as an ion implantation mask.

20. The method of claim 18, wherein forming the first impurity region comprises:
removing the photoresist pattern after etching the first preliminary gate insulation layer and the second preliminary gate insulation layer; and
implanting ions into the semiconductor substrate.
